(19) United States
(12) Patent Application Publication
(10) Pub. No.: US 2025/0338402 A1
(43) Pub. Date: Oct. 30, 2025

(54) ELECTRONIC DEVICE AND METHOD OF MANUFACTURING THE SAME

(71) Applicant: InnoLux Corporation, Miao-Li County (TW)

(72) Inventors: Ker-Yih KAO, Miao-Li County (TW); Po-Yun HSU, Miao-Li County (TW); Ju-Li WANG, Miao-Li County (TW)

(21) Appl. No.: 19/098,057

(22) Filed: Apr. 2, 2025

Related U.S. Application Data
(60) Provisional application No. 63/640,022, filed on Apr. 29, 2024.

(30) Foreign Application Priority Data
Sep. 20, 2024 (CN) 202411316164.5

(51) Int. Cl. H05K 1/14; H05K 1/11; H05K 3/42; H05K 3/46

(52) U.S. Cl. CPC H05K 1/145; H05K 1/115; H05K 3/42; H05K 3/4644; H05K 2201/09563

(57) ABSTRACT

An electronic device is provided. The electronic device includes a substrate, a through hole, a first circuit structure, and an electronic unit. The substrate includes a first side and a second side opposite to the first side. The through hole penetrates the substrate and connects the first side to the second side. The first circuit structure is disposed on the first side and includes a first metal layer and a first dielectric layer. The first metal layer overlaps a first portion of the first side. The first dielectric layer overlaps a second portion of the first side. The first portion is connected to the second portion. The electronic unit is electrically connected to the first circuit structure. Moreover, a surface roughness of the first portion is lower than a surface roughness of the second portion.

### CROSS REFERENCE TO RELATED APPLICATIONS

This application claims the benefit of China Application No. 202411316164.5, filed Sep. 20, 2024, which claims the benefit of provisional Application No. 63/640,022, filed Apr. 29, 2024, the entirety of which are incorporated by reference herein.

### BACKGROUND

### Technical Field

The present disclosure is related to an electronic device and a method of manufacturing the same, and in particular it is related to an electronic device that can improve the bonding strength between a through-hole substrate and a film layer, and a method of manufacturing the same.

### Description of the Related Art

Packaging technology can increase the integration density of electronic components (e.g., transistors, diodes, resistors, capacitors, etc.) in a given area. It has been widely used in the production and manufacturing of electronic devices in recent years. As the packaging size of semiconductors becomes smaller, the reliability requirements for chip manufacturing and packaging technology are also getting higher.

2.5D or 3D advanced packaging technology using three-dimensional packaging stacks the chips and then packages them on the substrate, thereby reducing the area taken up by the chips. This can reduce costs and lower the power consumption required to drive the chips. Such electronic devices often use substrates with through-holes as circuit transfer layers or interposers. Through-hole substrates can improve the electrical performance of the electronic devices or the flexibility of the stacking design. In a general process, a dielectric layer is formed on the through-hole substrate. However, due to the different coefficients of thermal expansion (CTE) of the dielectric layer and the through-hole substrate, the strength of the bond between the dielectric layer and the substrate is poor. Therefore, delamination or cracking may occur at the bonding position.

Based on the above, developing structural and process designs that can improve the reliability of electronic devices (for example, by increasing the bonding strength between different layers) is still one of the current research topics in the industry.

### SUMMARY

In accordance with some embodiments of the present disclosure, an electronic device is provided. The electronic device includes a substrate, a through hole, a first circuit structure and an electronic unit. The substrate includes a first side and a second side opposite to the first side. The through hole penetrates the substrate and connects the first side to the second side. The first circuit structure is disposed on the first side of the substrate and includes a first metal layer and a first dielectric layer. The first metal layer overlaps a first portion of the first side of the substrate. The first dielectric layer overlaps a second portion of the first side of the substrate. The first portion is connected to the second portion. The electronic unit is electrically connected to the first circuit structure. Furthermore, the surface roughness of the first portion is lower than the surface roughness of the second portion.

In accordance with some other embodiments of the present disclosure, a method of manufacturing an electronic device is provided. The method includes providing a substrate. The substrate includes a first side and a second side opposite to the first side. The method includes forming a through hole penetrating the substrate. The through hole connects the first side to the second side. The method includes forming a first circuit structure on the first side of the substrate. Forming the first circuit structure includes forming a first metal layer on the first side of the substrate, and forming a first dielectric layer on the first side of the substrate and covering the first metal layer. The first metal layer overlaps a first portion of the first side of the substrate. The first dielectric layer overlaps a second portion of the first side of the substrate. The first portion is connected to the second portion. Furthermore, the method includes performing a surface treatment process on the first side of the substrate, so that the surface roughness of the first portion is lower than the surface roughness of the second portion. The method further includes forming an electronic unit. The electronic unit is electrically connected to the first circuit structure.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A to 1D are cross-sectional diagrams of an electronic device during the different stages of the manufacturing process in accordance with some embodiments of the present disclosure;

FIGS. 2A to 2D are cross-sectional diagrams of an electronic device during the different stages of the manufacturing process in accordance with some embodiments of the present disclosure;

FIGS. 3A to 3C are cross-sectional diagrams of an electronic device during the different stages of the manufacturing process in accordance with some embodiments of the present disclosure;

FIGS. 4A to 4C are cross-sectional diagrams of an electronic device during the different stages of the manufacturing process in accordance with some embodiments of the present disclosure;

FIG. 5 is a cross-sectional diagram of an electronic device in accordance with some embodiments of the present disclosure;

FIG. 6 is a cross-sectional diagram of an electronic device in accordance with some embodiments of the present disclosure.

### DETAILED DESCRIPTION

The electronic device and the method of manufacturing the electronic device according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean+/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness, height, volume or area of each element, or spacing or distance between elements. Specifically, in accordance with some embodiments, a scanning electron microscope can be used to obtain a cross-sectional image including the elements to be measured, and measure the width, thickness, height, volume or area of each element, or spacing or distance between elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiment of the present disclosure, the provided electronic device and its manufacturing method can improve the bonding strength between the through-hole substrate and other film layers of different materials, thereby improving the reliability and performance of the electronic device.

In accordance with the embodiments of the present disclosure, the electronic device can be applied to power modules, semiconductor packaging devices, display devices, light-emitting devices, backlight devices, antenna devices, touch devices, sensing devices, wearable devices, automotive devices, battery device or tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components, and electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (quantum dot LED), but it is not limited thereto. In accordance with some embodiments, the electronic device may include a panel and/or a backlight module. The panel may include, for example, a liquid-crystal panel or another self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

In accordance with the embodiments of the present disclosure, the manufacturing method of the electronic device provided may be applied, for example, to a wafer-level package (WLP) or panel-level package (PLP) process, and the chip first process or the chip last/RDL first process may be used, which will be explained in further detail below.

Furthermore, in accordance with the embodiments of the present disclosure, the electronic device may be applied to a packaging structure, and the packaging structure may include System on Chip (SoC), System in Package (SiP), Chip on Wafer on Substrate (CoWoS) packaging, System on Integrated Chip (SoIC), Antenna in Package (AiP), Co-Packaged Optics (CPO), Micro Electro Mechanical System (MEMS) or a combination thereof, but it is not limited thereto.

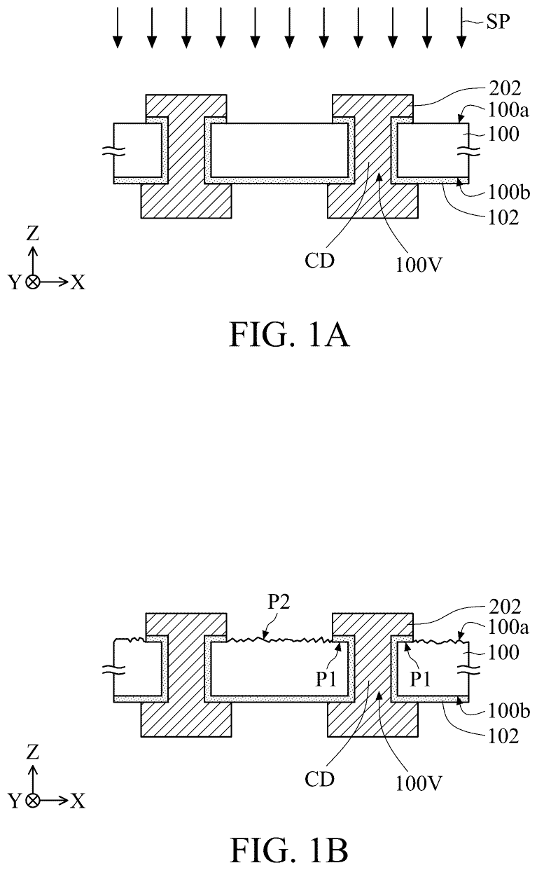

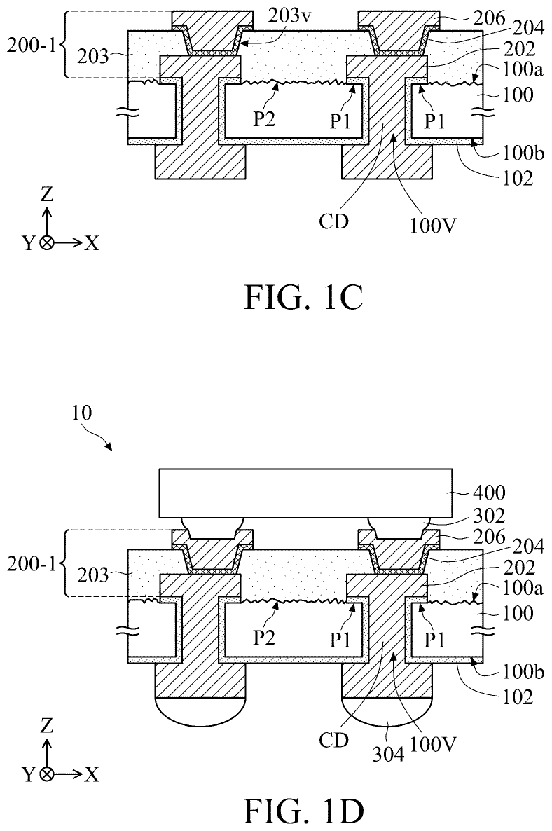

Please refer to FIGS. 1A to 1D, which are cross-sectional diagrams of an electronic device 10 during the different stages of the manufacturing process in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below. In addition, it should be understood that, in accordance with some embodiments, additional operation steps may be provided before, during, and/or after the method of manufacturing the electronic device 10. In accordance with some embodiments, some of the operation steps described may be replaced or omitted, and the order of some of the operation steps described may be interchangeable.

Referring to FIG. 1A, a substrate 100 is provided. The substrate 100 includes a first side 100a and a second side 100b opposite to the first side 100a. In accordance with some embodiments, the substrate 100 may include organic materials or inorganic materials. In accordance with some embodiments, the substrate 100 may include a silicon-containing substrate, glass or another suitable material, but it is not limited thereto. In accordance with some embodiments, the substrate 100 may include a transparent glass substrate, and the coefficient of thermal expansion (CTE) of the substrate 100 may be between 2 ppm/° C. and 15 ppm/° C. In accordance with some embodiments, the thickness of the substrate 100 may be between 40 millimeters (mm) to 800 millimeters.

Next, a through hole 100V is formed to penetrate the substrate 100, and the through hole 100V connects the first side 100a to the second side 100b. As shown in FIG. 1A, in accordance with some embodiments, the widths of the through hole 100V on the first side 100a and the second side 100b of the substrate 100 may be substantially the same. In accordance with some other embodiments, the width of the through hole 100V on the first side 100a of the substrate 100 may be greater than the width on the second side 100b. In other words, the width of the through hole 100V may gradually decrease from the first side 100a to the second side 100b. Alternatively, in accordance with some other embodiments, the width of the through hole 100V on the first side 100a of the substrate 100 may be smaller than the width on the second side 100b. In other words, the width of the through hole 100V may gradually increase from the first side 100a to the second side 100b. Alternatively, in accordance with still some other embodiments, the widths of the through hole 100V on the first side 100a and the second side 100b of the substrate 100 may be greater than the width of the portion between the first side 100a and the second side 100b. In addition, in accordance with some embodiments, in a top-view diagram (e.g., XY plane in the drawing), the through hole 100V may have a circular, quasi-circular, rectangular, etc. outline, but it is not limited thereto.

In accordance with some embodiments, the substrate 100 may be locally modified (for example, breaking the bonds of the substrate material or changing the strength of the substrate) through a laser process, and then the through hole 100V may be formed through a laser drilling process or etching process. In accordance with some embodiments, the through hole 100V may also be formed directly by laser. In accordance with some embodiments, the substrate 100 with the through hole 100V may be referred to as a through glass via (TGV).

In accordance with some embodiments, a buffer layer 102 may then be formed on the substrate 100 and extend into the through hole 100V. In detail, the buffer layer 102 may be formed on at least part of the first side 100a of the substrate 100, at least part of the side surface of the through hole 100V, and at least part of the second side 100b. In accordance with some embodiments, the thermal expansion coefficient of the buffer layer 102 may be greater than the thermal expansion coefficient of the substrate 100, and the buffer layer 102 may absorb stress and protect the substrate 100. In accordance with some embodiments, the toughness of the buffer layer 102 may be between 0.1 kJ/m² and 100 KJ/m² (that is, 0.1 kJ/m²≤the toughness of the buffer layer 102≤100 KJ/m²), between 1 kJ/m² and 90 KJ/m², or between 10 kJ/m² and 80 kJ/m², for example, 20 KJ/m², 30 KJ/m², 40 KJ/m², 50 KJ/m², 60 kJ/m² or 70 KJ/m², but it is not limited thereto. In accordance with some embodiments, the thickness of the buffer layer 102 may be between 0.01 micrometers (μm) and 10 μm (that is, 0.01 μm≤the thickness of the buffer layer 102≤10 μm), between 0.1 μm and 9.5 μm, or between 1 μm and 9 μm, for example, 1.5 μm, 2 μm, 2.5 μm, 3 μm, 3.5 μm, 4 μm, 4.5 μm, 5 μm, 5.5 μm, 6 μm, 6.5 μm, 7 μm, 7.5 μm, 8 μm or 8.5 μm, but it is not limited thereto. Furthermore, in accordance with some embodiments, the ratio of the thickness of the buffer layer 102 to the diameter of the through hole 100V may be between 0.02 and 0.2 (that is, 0.02≤thickness of the buffer layer 102/diameter of the through hole 100V≤0.2), for example, 0.03, 0.04, 0.05, 0.06, 0.07, 0.08, 0.09, 0.1, 0.11, 0.12, 0.13, 0.14, 0.15, 0.16, 0.17, 0.18 or 0.19, but it is not limited thereto.

The thickness of the buffer layer 102 refers to the maximum thickness of the buffer layer 102 in the normal direction of the substrate 100 (for example, the Z direction in the figure). Furthermore, if the through hole 100V is circular, the diameter of the aforementioned through hole 100V refers to the diameter of the through hole 100V in the top-view diagram; if the through hole 100V is not circular, a smallest circle can be drawn to surround the through hole 100V, and the diameter of the smallest circle is defined as the diameter of the through hole 100V.

In accordance with some embodiments, buffer layer 102 may include a single layer or multiple layers. The material of the buffer layer 102 may include polyimide, parylene, benzocyclobutene (BCB), epoxy resin, polycarbonate (PC), polyethylene terephthalate (PET), polyethylene naphthalate (PEN), silicon oxide (SiOx), silicon nitride (SiNx), and another suitable buffer material or a combination thereof, but it is not limited thereto. In accordance with some embodiments, the buffer layer 102 may be formed by a coating process, a chemical vapor deposition process, another suitable method, or a combination thereof. In accordance with some embodiments, the buffer layer 102 may include a first sub-layer and a second sub-layer. The first sub-layer may be disposed between the second sub-layer and the glass substrate 100. The toughness of the first sub-layer may be greater than that of the second sub-layer, thereby absorbing stress and protecting the substrate 100.

Next, a conductive element CD is formed in the through hole 100V, and the conductive element CD is formed on the buffer layer 102. Furthermore, a metal layer 202 is formed on the first side 100a of the substrate 100. Specifically, in accordance with some embodiments, the conductive material may be formed in the through hole 100V, and the conductive material may also partially extend and protrude on the first side 100a and the second side 100b of the substrate 100. The conductive material located in the through hole 100V can be used as the conductive element CD, and the conductive material located on the first side 100a of the substrate 100 can be used as the metal layer 202 of the first circuit structure 200-1 (for example, please refer to FIG. 1C), but it is not limited thereto. Furthermore, the conductive element CD and the metal layer 202 may be formed in the same process, or may be formed separately in different processes.

In accordance with some embodiments, the conductive material of the conductive element CD and the metal layer 202 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), ruthenium (Ru), alloys of the aforementioned metals, another suitable material or a combination thereof, but it is not limited thereto. In accordance with some embodiments, the conductive material may be formed by a physical vapor deposition process, an electroplating process, an electroless plating process, another suitable method, or a combination thereof. Furthermore, the conductive material may be patterned through one or more photolithography processes and/or etching processes to form the metal layer 202. In addition, in accordance with some embodiments, in addition to removing a portion of the conductive material, the aforementioned patterning step also removes a portion of the buffer layer 102 to expose part of the surface of the first side 100a of the substrate 100. In accordance with some embodiments, the aforementioned photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto. Furthermore, the conductive element CD and the metal layer 202 may have a single-layer or multi-layer structure.

Please continuing to refer to FIG. 1A, a surface treatment process SP is performed on the first side 100a of the substrate 100. Specifically, the surface treatment process SP may roughen the exposed surface of the first side 100a of the substrate 100. In accordance with some embodiments, the surface treatment process SP may include a laser roughening process, a chemical etching process, a mechanical grinding process, another suitable process, or a combination thereof. In accordance with some embodiments, an acidic etching solution or an alkaline etching solution may be used to perform the chemical etching process.

As shown in FIG. 1B, after the surface treatment process SP is performed on the first side 100a of the substrate 100, a portion P2 of the first side 100a of the substrate 100 is roughened, and a portion P1 of the first side 100a of the substrate 100 is not roughened. Specifically, the surface treatment process SP roughens the portion P2 not covered by the metal layer 202, while the portion P1 covered by the metal layer 202 is not roughened. The surface treatment process SP makes the surface roughness of the portion P1 lower than the surface roughness of the portion P2. In accordance with some embodiments, the ratio of the surface roughness of the portion P2 to the surface roughness of the portion P1 is greater than or equal to 1.02 and less than or equal to 1.5 (that is, 1.02≤surface roughness of the portion P2/surface roughness of the portion P1≤1.5), or the ratio of the surface roughness of the portion P2 to the surface roughness of the portion P1 is greater than or equal to 1.05 and less than or equal to 1.45, for example, 1.1, 1.15, 1.2, 1.25, 1.3, 1.35 or 1.4, but it is not limited thereto. Specifically, in accordance with some embodiments, the surface roughness of the portion P1 of the first side 100a of the substrate 100 may be between 0.1 μm and 3 μm, or between 0.1 μm and 1 μm. In accordance with some embodiments, the surface roughness of the portion P2 of the first side 100a of the substrate 100 may be between 0.01 μm and 4.5 μm, or between 0.1 μm and 1.5 μm.

In accordance with the embodiments of the present disclosure, the roughened surface refers to a distance difference between 0.15 μm and 1 μm between the peaks and valleys of the surface undulations when observed with an electron microscope. The roughness can be determined by using a scanning electron microscope (SEM) or a transmission electron microscope (TEM) to observe the surface undulations at appropriate magnification. In addition, the surface undulating conditions are compared in a unit length (for example, 10 μm). Herein, “appropriate magnification” means that at least 10 undulating peaks and valleys can be observed on at least one surface under this magnification. In addition, according to embodiments of the present disclosure, roughness can be expressed by arithmetic average roughness (Ra) or maximum peak-to-valley height (Rz). Ra represents the average value of surface profile deviation, which is the result of averaging the absolute values of the deviation of each measuring point from the average line in the measurement area. Rz refers to taking several intervals of equal length in the measurement area, calculating the distance between the highest peak and the lowest valley in each interval, and then taking the average of these intervals as Rz.

Referring to FIG. 1C, a dielectric layer 203 is then formed on the first side 100a of the substrate 100 and covers the metal layer 202. Specifically, after performing the surface treatment process SP on the first side 100a of the substrate 100, the dielectric layer 203 is formed on the first side 100a of the substrate 100 and covers the metal layer 202. The dielectric layer 203 may be in contact with the first side 100a of the substrate 100, the metal layer 202, and the buffer layer 102. As shown in FIG. 1C, the metal layer 202 overlaps the portion P1 of the first side 100a of the substrate 100, the dielectric layer 203 overlaps the portion P2 of the first side 100a of the substrate 100, and the portion P1 is connected to the portion P2. Specifically, in the normal direction of the substrate 100 (e.g., the Z direction in the figure), the metal layer 202 overlaps the portion P1, and the dielectric layer 203 overlaps the portion P2. In addition, the metal layer 202 and the dielectric layer 203 can serve as the first circuit structure 200-1. At this stage, the first circuit structure 200-1 is formed on the first side 100a of the substrate 100. In accordance with some embodiments, the first circuit structure 200-1 can serve as a redistribution layer (RDL) of the electronic device, and can include at least one conductive layer (e.g., metal layer 202) and at least one dielectric layer (e.g., dielectric layer 203), which can redistribute the circuits of the electronic device and/or further increase the circuit fan-out area, or different electronic components can be electrically connected to each other through the first circuit structure 200-1. The redistribution layer can extend a wire to a wider spacing or reroute a wire to another wire with a different spacing, and/or the redistribution layer can serve as the electrical interface route between one connection and another of substrate. For example, the pitch of two adjacent contact pads on the end of the redistribution layer that contacts the electronic component can be less than or equal to the pitch of two adjacent contact pads on the end of the redistribution layer away from the electronic component. Therefore, the redistribution layer can adjust the circuit fan-out condition or electrically connect the circuit structure/electronic component with the first pitch to the circuit structure/electronic component with the second pitch, but it is not limited thereto. The method of forming the redistribution layer may include providing a stack of at least one conductive layer and at least one dielectric layer. The method of forming the redistribution layer may include photolithography, etching, surface treatment, laser, electroplating, chemical plating, deposition, atomic layer deposition and other processes. The surface treatment may include roughening or activating the surface of the dielectric layer or the surface of the conductive layer to improve the adhesion ability of the dielectric layer or conductive layer. For example, by increasing the surface roughness, the bonding strength between subsequent layers can be improved. In accordance with some embodiments, when the redistribution layer has multiple dielectric layers 203, the thermal expansion coefficients of the dielectric layers may be the same or different. Furthermore, when the thermal expansion coefficients of the dielectric layers are different, the thermal expansion coefficient of the dielectric layer close to the electronic unit 400 is smaller than the thermal expansion coefficient of the dielectric layer far away from the electronic unit 400.

Furthermore, the material of the dielectric layer 203 may include inorganic materials, organic materials, or a combination thereof, but it is not limited thereto. In accordance with some embodiments, the inorganic material may include silicon nitride, silicon oxide, silicon oxynitride, another suitable material, or a combination thereof, but it is not limited thereto. In accordance with some embodiments, the organic material may include polyimide (PI), photosensitive polyimide (PSPI), polybenzoxazole (PBO), benzocyclobutene (BCB), epoxy resin, Ajinomoto Build-up Film (ABF) build-up material, another suitable material or a combination thereof, but it is not limited thereto. In accordance with some embodiments, the dielectric layer 203 may be formed by a coating process, a chemical vapor deposition process, another suitable method, or a combination thereof.

It should be noted that since the thermal expansion coefficient of the dielectric layer 203 is different from that of the substrate 100, the bonding strength between the dielectric layer 203 and the substrate 100 is affected. However, by arranging the surface roughness of the portion P1 to be lower than the surface roughness of the portion P2, the dielectric layer 203 is in contact with the roughened portion P2, which can enhance the joint strength between the substrate 100 and the dielectric layer 203, thereby improving the reliability and performance of the electronic device. In particular, when the ratio of the surface roughness of the portion P2 to the surface roughness of the portion P1 is within the aforementioned range (for example, greater than or equal to 1.02 and less than or equal to 1.5), the bonding strength between the substrate 100 and the dielectric layer 203 can be significantly improved, but will not cause dielectric loss or affect the transmission of electrical signals due to excessive surface treatment.

Please continue to refer to FIG. 1C. In accordance with some embodiments, a portion of the dielectric layer 203 is removed to form a through hole 203V, and then the conductive layer 204 is formed on the dielectric layer 203. Moreover, the conductive layer 204 may extend into the through hole 203V. The conductive layer 204 can serve as a seed layer to facilitate the subsequent formation of a conductive element 206. In accordance with some embodiments, the conductive layer 204 and the conductive element 206 may also be part of the first circuit structure 200-1. In accordance with some embodiments, the conductive layer 204 may include metal materials, such as copper (Cu), titanium (Ti), aluminum (Al), tungsten (W), silver (Ag), gold (Au), molybdenum (Mo), chromium (Cr), nickel (Ni), tantalum (Ta), ruthenium (Ru), or another suitable metal material, but it is not limited thereto. In accordance with some embodiments, the conductive layer 204 may be a composite layer, for example, including a titanium layer and a copper layer as sub-layers, but it is not limited thereto. In accordance with some embodiments, the conductive layer 204 may be formed by a physical vapor deposition (PVD) process, an atomic layer deposition (ALD) process, an electroplating process, an electroless plating process, another suitable method, or a combination thereof. In addition, the conductive layer 204 may be patterned through one or more photolithography processes and/or etching processes to define the position of the subsequently formed conductive element 206.

Next, the conductive element 206 is formed in the through hole 203V. The conductive element 206 may be in contact with the conductive layer 204, and the conductive element 206 may be electrically connected to the conductive layer 204. In accordance with some embodiments, the material of the conductive element 206 may include copper (Cu), titanium (Ti), aluminum (Al), tungsten (W), silver (Ag), gold (Au), tin (Sn), molybdenum (Mo), chromium (Cr), nickel (Ni), platinum (Pt), gallium (Ga), tantalum (Ta), ruthenium (Ru), alloys of the aforementioned metals, another suitable material or a combination thereof, but it is not limited thereto. In accordance with some embodiments, the conductive element 206 may be formed by a physical vapor deposition process, an electroplating process, an electroless plating process, another suitable method, or a combination thereof.

Please refer to FIG. 1D. Next, the electronic unit 400 is formed, and the electronic unit 400 is electrically connected to the first circuit structure 200-1. In detail, in accordance with some embodiments, the conductive element 206 can serve as a contact pad, and a connecting element 302 may be formed on the first circuit structure 200-1. The electronic unit 400 may be electrically connected to the first circuit structure 200-1 through the connecting element 302. Specifically, in accordance with some embodiments, the connecting element 302 may be disposed corresponding to the conductive element 206 of the first circuit structure 200-1 and the electronic unit 400. That is, in the normal direction of the substrate 100 (e.g., the Z direction in the figure), the connecting element 302 may overlap the conductive element 206 and the electronic unit 400.

In accordance with some embodiments, the electronic unit 400 may include, for example, a known-good die (KGD), an integrated circuit chip (IC), or a surface mount device (SMD), a diode or another suitable electronic component, but it is not limited thereto. Specifically, in accordance with some embodiments, the electronic unit 400 may include a system on a chip, a dynamic random access memory, a high-bandwidth memory, a photonic integrated circuit, an application-specific integrated circuit, or another logic integrated circuit.

In accordance with some embodiments, the material of the connecting element 302 may include tin, silver, lead-free tin, copper, nickel, gold, another suitable material or combinations thereof, but it is not limited thereto. In accordance with some embodiments, the connecting element 302 may be bonded onto the conductive element 206 of the first circuit structure 200-1 through a reflow process, a fusion bonding process, a hybrid bonding process, a metal-to-metal bonding process, another suitable method, or a combination thereof. The electronic unit 400 is thereby bonded to the first circuit structure 200-1.

Furthermore, in accordance with some embodiments, the connecting element 304 may also be formed on the second side 100b of the substrate 100, and the connecting element 304 may be electrically connected to the conductive element CD. In accordance with some embodiments, the connecting element 304 may be further electrically connected to external electronic components. For example, the connecting element 304 may be further electrically connected to a printed circuit board (PCB), a chip, a control component or another electronic component (not illustrated), but the present disclosure is not limited thereto.

Referring to FIG. 1D, the electronic device 10 may include a substrate 100, a through hole 100V, a first circuit structure 200-1 and an electronic unit 400. The substrate 100 includes a first side 100a and a second side 100b opposite to the first side 100a. The through hole 100V penetrates the substrate 100 and connects the first side 100a to the second side 100b. The first circuit structure 200-1 is disposed on the first side 100a of the substrate 100 and includes a metal layer 202 and a dielectric layer 203. The metal layer 202 overlaps a portion P1 of the first side 100a of the substrate 100, the dielectric layer 203 overlaps a portion P2 of the first side 100a of the substrate 100, and the portion P1 is connected to the portion P2. The electronic unit 400 is electrically connected to the first circuit structure 200-1. Furthermore, the surface roughness of the portion P1 is lower than the surface roughness of the portion P2.

In accordance with some embodiments, the ratio of the surface roughness of the portion P2 to the surface roughness of the portion P1 is greater than or equal to 1.02 and less than or equal to 1.5 (that is, 1.02≤surface roughness of the portion P2/surface roughness of the portion P1≤1.5), or the ratio of the surface roughness of portion P2 to the surface roughness of portion P1 is greater than or equal to 1.05 and less than or equal to 1.45, for example, 1.1, 1.15, 1.2, 1.25, 1.3, 1.35 or 1.4, but it is not limited thereto.

In accordance with some embodiments, the electronic device 10 may further include a buffer layer 102, and the buffer layer 102 may be disposed between the metal layer 202 and the substrate 100. Furthermore, the buffer layer 102 may extend into the through hole 100V. Furthermore, in accordance with some embodiments, the electronic device 10 may further include a conductive layer 204, a conductive element 206, a connecting element 302 and a connecting element 304. The conductive layer 204 and the conductive element 206 may be electrically connected to the metal layer 202. The first circuit structure 200-1 may be electrically connected to the electronic unit 400 through the connecting element 302.

As described above, in the embodiments shown in FIGS. 1A to 1D, after the through hole 100V is formed to penetrate the substrate 100, the first circuit structure 200-1 is formed on the first side 100a of the substrate 100. In other words, the embodiments shown in FIGS. 1A to 1D adopt a via-first process.

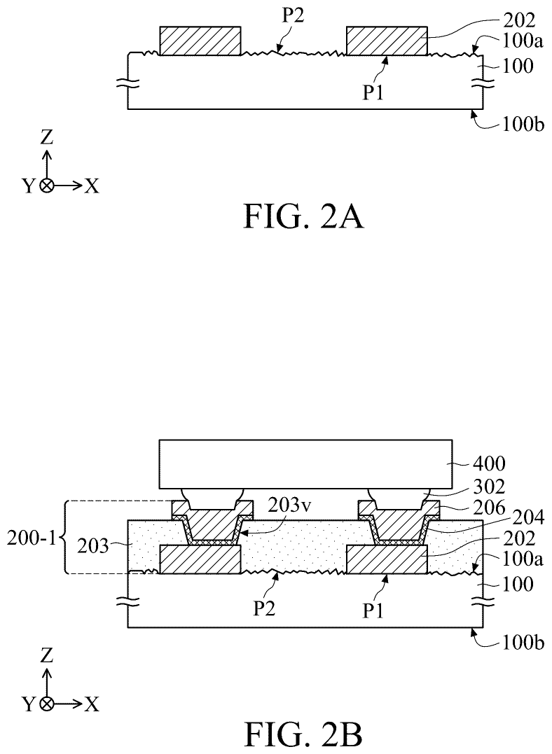

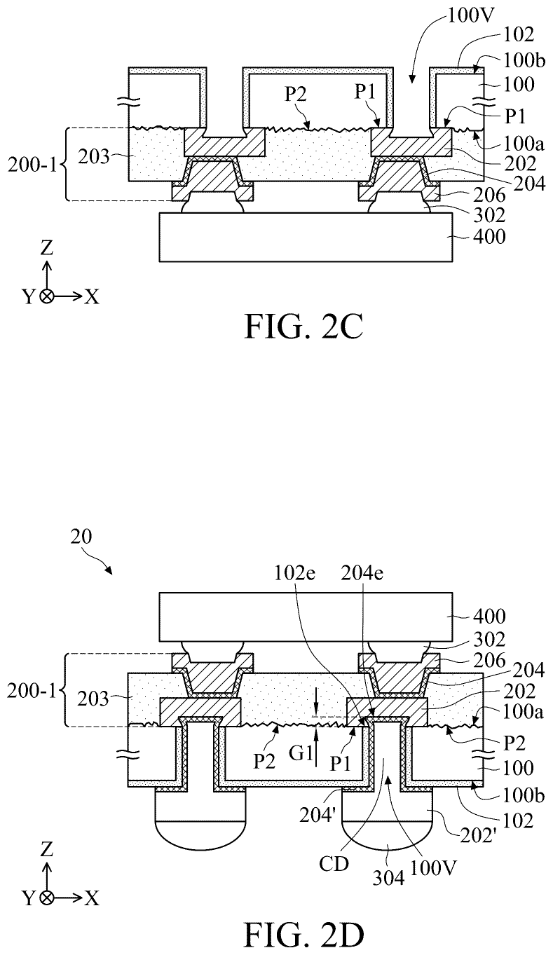

Please refer to FIGS. 2A to 2D, which are cross-sectional diagrams of an electronic device 20 during the different stages of the manufacturing process in accordance with some embodiments of the present disclosure. It should be understood that, for clarity of explanation, some components of the electronic device 20 may be omitted in the drawings, and only some components are schematically illustrated. In accordance with some embodiments, additional features may be added to the electronic device 20 described below. In addition, it should be understood that, in accordance with some embodiments, additional operation steps may be provided before, during, and/or after the method of manufacturing the electronic device 20. In accordance with some embodiments, some of the operation steps described may be replaced or omitted, and the order of some of the operation steps described may be interchangeable. In addition, the components or elements that are the same or similar to those mentioned above will be represented by the same or similar numbers below, and their materials and functions are the same or similar as those mentioned above, and thus will not be repeated in the following description.

Referring to FIG. 2A, a substrate 100 is provided. The substrate 100 includes a first side 100a and a second side 100b opposite to the first side 100a. A metal layer 202 is formed on the substrate 100. In this embodiment, the surface treatment process SP is performed on the first side 100a of the substrate 100 first. As shown in FIG. 2A, after the surface treatment process SP is performed on the first side 100a of the substrate 100, a portion P2 of the first side 100a of the substrate 100 is roughened, while a portion P1 of the first side 100a of the substrate 100 is not roughened. Specifically, the surface treatment process SP roughens the portion P2 not covered by the metal layer 202, while the portion P1 covered by the metal layer 202 is not roughened. The surface treatment process SP makes the surface roughness of the portion P1 lower than the surface roughness of the portion P2. In accordance with some embodiments, the ratio of the surface roughness of the portion P2 to the surface roughness of the portion P1 is greater than or equal to 1.02 and less than or equal to 1.5 (that is, 1.02≤surface roughness of the portion P2/surface roughness of the portion P1≤1.5), or the ratio of the surface roughness of the portion P2 to the surface roughness of the portion P1 is greater than or equal to 1.05 and less than or equal to 1.45, for example, 1.1, 1.15, 1.2, 1.25, 1.3, 1.35 or 1.4, but it is not limited thereto. Specifically, in accordance with some embodiments, the surface roughness of the portion P1 of the first side 100a of the substrate 100 may be between 0.01 μm and 3 μm, or between 0.1 μm and 1 μm. In accordance with some embodiments, the surface roughness of the portion P2 of the first side 100a of the substrate 100 may be between 0.01 μm and 4.5 μm, or between 0.1 μm and 1.5 μm.

Please referring to FIG. 2B, a dielectric layer 203 then is formed on the first side 100a of the substrate 100 and covering the metal layer 202. Specifically, after performing the surface treatment process SP on the first side 100a of the substrate 100, the dielectric layer 203 is formed on the first side 100a of the substrate 100 and covers the metal layer 202. The dielectric layer 203 may be in contact with the first side 100a of the substrate 100 and the metal layer 202. As shown in FIG. 2B, the metal layer 202 overlaps the portion P1 of the first side 100a of the substrate 100, the dielectric layer 203 overlaps the portion P2 of the first side 100a of the substrate 100, and the portion P1 is connected to the portion P2. In addition, the metal layer 202 and the dielectric layer 203 can serve as the first circuit structure 200-1. At this stage, the first circuit structure 200-1 is formed on the first side 100a of the substrate 100.

Continuing to refer to FIG. 2B. In accordance with some embodiments, a portion of the dielectric layer 203 is removed to form a through hole 203V, and then a conductive layer 204 is formed on the dielectric layer 203. The conductive layer 204 may extend into the through hole 203V. Next, a conductive element 206 may be formed in the through hole 203V. The conductive element 206 may be in contact with the conductive layer 204, and the conductive element 206 may be electrically connected to the conductive layer 204. In accordance with some embodiments, the first circuit structure 200-1 may include the metal layer 202, the dielectric layer 203, the conductive layer 204, and the conductive element 206.

Next, an electronic unit 400 can be formed, and the electronic unit 400 is electrically connected to the first circuit structure 200-1. In detail, in accordance with some embodiments, the conductive element 206 can serve as a contact pad, and a connecting element 302 may be formed on the first circuit structure 200-1. The electronic unit 400 may be electrically connected to the first circuit structure 200-1 through the connecting element 302. Specifically, in accordance with some embodiments, the connecting element 302 may be disposed corresponding to the conductive element 206 of the first circuit structure 200-1 and the electronic unit 400. That is, in the normal direction of the substrate 100 (e.g., the Z direction in the figure), the connecting element 302 may overlap with the conductive element 206 and the electronic unit 400.

Referring to FIG. 2C, the above structure is flipped, and a through hole 100V is formed penetrating the substrate 100 from the second side 100b of the substrate 100. The through hole 100V connects the first side 100a to the second side 100b. A portion of the substrate 100 may be removed through one or more photolithography processes and/or etching processes to form the through hole 100V. Next, a buffer layer 102 may be formed on the substrate 100 and extend into the through hole 100V. Specifically, the buffer layer 102 may be formed on the second side 100b of the substrate 100, the side surface and the bottom surface of the through hole 100V. Thereafter, the buffer layer 102 located on the bottom surface of the through hole 100V may be removed through one or more photolithography processes and/or etching processes. In accordance with some embodiments, the step of removing the buffer layer 102 also removes a portion of the metal layer 202. As shown in FIG. 2C, in accordance with some embodiments, the through hole 100V may partially extend to the metal layer 202, and the bottom surface of the through hole 100V may be lower than the portion P1 of the first side 100a of the substrate 100.

Please refer to FIG. 2D. in accordance with some embodiments, a conductive layer 204′ may be formed on the buffer layer 102, and the conductive layer 204′ may extend into the through hole 100V. The conductive layer 204′ may contact with the metal layer 202, and the conductive layer 204′ may be electrically connected to the metal layer 202. Furthermore, the conductive layer 204′ can serve as a seed layer. As shown in FIG. 2D, in accordance with some embodiments, an end 204e of the conductive layer 204′ may protrude from an end 102e of the buffer layer 102 by a first distance G1, and the first distance G1 may be less than or equal to 2 micrometers (i.e. the first distance G1 distance G1≤2 μm), for example, less than or equal to 1.5 μm, 1 μm or 0.5 μm. Moreover, the first distance G1 may be greater than 0.

Next, a conductive element CD is formed in the through hole 100V, and the conductive element CD is formed on the conductive layer 204′. Furthermore, a metal layer 202′ may be formed on the second side 100b of the substrate 100. Specifically, in accordance with some embodiments, the conductive material may be formed in the through hole 100V, and the conductive material may also partially extend and protrude from the second side 100b of the substrate 100. The conductive material located in the through hole 100V can serve as the conductive element CD, and the conductive material protruding from the second side 100b of the substrate 100 may be a metal layer 202′, but it is not limited thereto. Furthermore, the conductive element CD and the metal layer 202′ may be formed in the same process, or may be formed separately in different processes.

In accordance with some embodiments, a connecting element 304 may be formed on the second side 100b of the substrate 100, and the connecting element 304 may be electrically connected to the metal layer 202′. In accordance with some embodiments, the connecting element 304 may be further electrically connected to external electronic components. For example, the connecting element 304 may be further electrically connected to a printed circuit board (PCB), a chip, a control element or another electronic component (not illustrated), but the present disclosure is not limited thereto.

Referring to FIG. 2D, the electronic device 20 may include a substrate 100, a through hole 100V, a first circuit structure 200-1 and an electronic unit 400. The substrate 100 includes a first side 100a and a second side 100b opposite to the first side 100a. The through hole 100V penetrates the substrate 100 and connects the first side 100a to the second side 100b. The first circuit structure 200-1 is disposed on the first side 100a of the substrate 100 and includes a metal layer 202 and a dielectric layer 203. The metal layer 202 overlaps a portion P1 of the first side 100a of the substrate 100, the dielectric layer 203 overlaps a portion P2 of the first side 100a of the substrate 100, and the portion P1 is connected to the portion P2. The electronic unit 400 is electrically connected to the first circuit structure 200-1. Furthermore, the surface roughness of the portion P1 is lower than the surface roughness of the portion P2. Similarly, in accordance with some embodiments, the ratio of the surface roughness of portion P2 to the surface roughness of portion P1 is greater than or equal to 1.02 and less than or equal to 1.5.

In accordance with some embodiments, the electronic device 20 may further include a buffer layer 102, and the buffer layer 102 may be disposed between the metal layer 202′ and the substrate 100. Furthermore, the buffer layer 102 may extend into the through hole 100V. In accordance with some embodiments, the electronic device 20 may further include a conductive layer 204′. The conductive layer 204′ may be disposed on the buffer layer 102 and extend into the through hole 100V. The end 204e of the conductive layer 204′ may protrude from the end 102e of the buffer layer 102 by a first distance G1, and the first distance G1 may be less than or equal to 2 micrometers.

Furthermore, in accordance with some embodiments, the electronic device 20 may further include a conductive layer 204, a conductive element 206, a connecting element 302 and a connecting element 304. The conductive layer 204 and the conductive element 206 may be electrically connected to the metal layer 202. The first circuit structure 200-1 may be electrically connected to the electronic unit 400 through the connecting component 302.

As described above, in the embodiment shown in FIGS. 2A to 2D, before forming the through hole 100V penetrating the substrate 100, the first circuit structure 200-1 is first formed on the first side 100a of the substrate 100. In other words, the embodiments shown in FIGS. 2A to 2D adopt a via-last process.

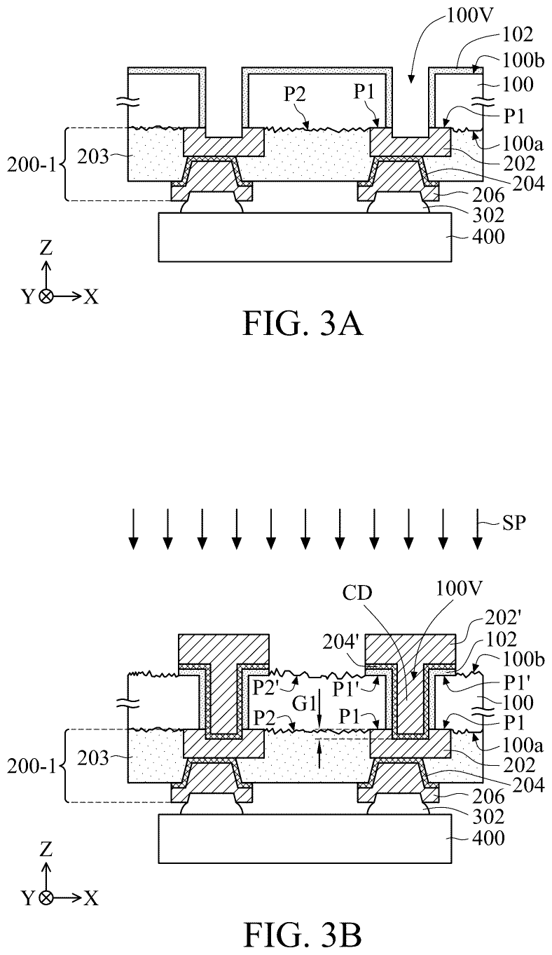

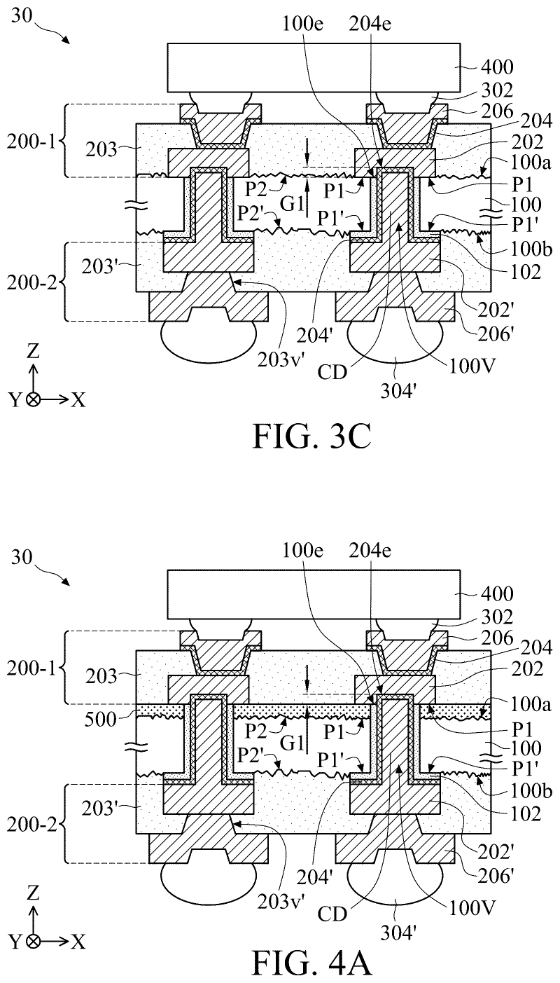

Please refer to FIGS. 3A to 3C, which are cross-sectional diagrams of an electronic device 30 during the different stages of the manufacturing process in accordance with some embodiments of the present disclosure. It should be understood that, for clarity of explanation, some components of the electronic device 30 may be omitted in the drawings, and only some components are schematically illustrated. In accordance with some embodiments, additional features may be added to the electronic device 30 described below. In addition, it should be understood that, in accordance with some embodiments, additional operation steps may be provided before, during, and/or after the method of manufacturing the electronic device 30. In accordance with some embodiments, some of the operation steps described may be replaced or omitted, and the order of some of the operation steps described may be interchangeable.

Please refer to FIG. 3A. FIG. 3A essentially continues the process steps shown in FIG. 2C. Specifically, in this embodiment, a substrate 100 is provided, and then a surface treatment process SP is performed on the first side 100a of the substrate 100 so that the surface roughness of the portion P1 is lower than the surface roughness of the portion P2. A dielectric layer 203 is formed on the first side 100a of the substrate 100 and covers a metal layer 202. A first circuit structure 200-1 is formed on the first side 100a of the substrate 100. An electronic unit 400 electrically connected to the first circuit structure 200-1 is formed. Furthermore, a through hole 100V penetrating the substrate 100 is formed from the second side 100b of the substrate 100, and a buffer layer 102 is formed on the substrate 100 and extends into the through hole 100V.

Please refer to FIG. 3B. In accordance with some embodiments, after the buffer layer 102 is formed in the through hole 100V, a conductive layer 204′ is formed on the buffer layer 102. The conductive layer 204′ extends in the through hole 100V. The conductive layer 204′ may contact the metal layer 202, and the conductive layer 204′ may be electrically connected to the metal layer 202. As mentioned above, in accordance with some embodiments, an end 204e of the conductive layer 204′ may protrude from an end 102e of the buffer layer 102 by a first distance G1, and the first distance G1 may be less than or equal to 2 μm (that is, the first distance G1≤2 μm), for example, less than or equal to 1.5 μm, 1 μm or 0.5 μm. Moreover, the first distance G1 may be greater than 0.

Next, a conductive element CD may be formed in the through hole 100V, and the conductive element CD may be formed on the conductive layer 204′. Furthermore, a metal layer 202′ may be formed on the second side 100b of the substrate 100. In particular, in this embodiment, after the metal layer 202′ is formed, a surface treatment process SP may be further performed on the second side 100b of the substrate 100. The surface treatment process SP can roughen the exposed surface of the second side 100b of the substrate 100.

As shown in FIG. 3B, after the surface treatment process SP is performed on the second side 100b of the substrate 100, a portion P2′ of the second side 100b of the substrate 100 is roughened, and a portion P1′ of the second side 100b of the substrate 100 is not roughened. Specifically, the surface treatment process SP roughens the portion P2′ not covered by the metal layer 202′, while the portion P1′ covered by the metal layer 202′ is not roughened. The surface treatment process SP makes the surface roughness of the portion P1′ smaller than the surface roughness of the portion P2′. In accordance with some embodiments, the ratio of the surface roughness of the portion P2′ to the surface roughness of the portion P1′ is greater than or equal to 1.02 and less than or equal to 1.5 (that is, 1.02≤surface roughness of the portion P2′/surface roughness of the portion P1′≤1.5), or the ratio of the surface roughness of portion P2′ to the surface roughness of portion P1′ is greater than or equal to 1.05 and less than or equal to 1.45, for example, 1.1, 1.15, 1.2, 1.25, 1.3, 1.35 or 1.4, but it is not limited thereto. Specifically, in accordance with some embodiments, the surface roughness of the portion P1′ of the second side 100b of the substrate 100 may be between 0.01 μm and 3 μm, or between 0.1 μm and 1 μm. In accordance with some embodiments, the surface roughness of the portion P2′ of the second side 100b of the substrate 100 may be between 0.01 μm and 4.5 μm, or between 0.1 μm and 1.5 μm.

Referring to FIG. 3C, a dielectric layer 203′ is then formed on the second side 100b of the substrate 100 and covers the metal layer 202′. Specifically, after performing the surface treatment process SP on the second side 100b of the substrate 100, the dielectric layer 203′ is formed on the second side 100b of the substrate 100 and covers the metal layer 202′. The dielectric layer 203′ may be in contact with the second side 100b of the substrate 100, the metal layer 202′, and the buffer layer 102. As shown in FIG. 3C, the metal layer 202′ overlaps the portion P1′ of the second side 100b of the substrate 100, the dielectric layer 203′ overlaps the portion P2′ of the second side 100b of the substrate 100, and the portion P1′ connects the second portion P2′. Specifically, in the normal direction of the substrate 100 (for example, the Z direction in the figure), the metal layer 202′ overlaps the portion P1′, and the dielectric layer 203′ overlaps the portion P2′. In addition, the metal layer 202′ and the dielectric layer 203′ can serve as a second circuit structure 200-2. At this step, the second circuit structure 200-2 is formed on the second side 100b of the substrate 100, and the first circuit structure 200-1 is electrically connected to the second circuit structure 200-2 through the conductive element CD. Particularly, in this embodiment, the electronic device 30 further includes the second circuit structure 200-2, and the second circuit structure 200-2 is disposed on the second side 100b of the substrate 100. In accordance with some embodiments, the second circuit structure 200-2 can serve as a redistribution layer (RDL) of the electronic device, and includes at least one conductive layer (e.g., metal layer 202′) and at least one dielectric layer (e.g., dielectric layer 203′), which can redistribute the circuits of the electronic device and/or further increase the circuit fan-out area, or different electronic components can be electrically connected to each other through the second circuit structure 200-2.

It should be noted that due to the large difference between the thermal expansion coefficient of the dielectric layer 203′ and the thermal expansion coefficient of the substrate 100 (the thermal expansion coefficient of the dielectric layer 203′ is greater than the thermal expansion coefficient of the substrate 100), the bonding strength between the dielectric layer 203′ and the substrate 100 may be affected. However, by arranging the surface roughness of the portion P1′ to be smaller than the surface roughness of the portion P2′, the dielectric layer 203′ is in contact with the roughened portion P2′, which can enhance the joint strength between the substrate 100 and the dielectric layer 203′, thereby improving the reliability and performance of the electronic device. In particular, when the ratio of the surface roughness of the portion P2′ to the surface roughness of the portion P1′ is within the aforementioned range (for example, greater than or equal to 1.02 and less than or equal to 1.5), the bonding strength between the substrate 100 and the dielectric layer 203′ can be significantly improved, but will not cause dielectric loss or affect the transmission of electrical signals due to excessive surface treatment.

Please continue to refer to FIG. 3C. In accordance with some embodiments, a portion of the dielectric layer 203′ may be removed to form a through hole 203V′, and then a conductive element 206′ may be formed on the dielectric layer 203′. The conductive element 206′ may be formed on the dielectric layer 203′, and the conductive element 206′ may extend into the through hole 203V′. The conductive element 206′ may contact the metal layer 202′, and the conductive element 206′ may be electrically connected to the metal layer 202′. In accordance with some embodiments, the conductive element 206′ may also be part of the second circuit structure 200-2. The conductive element 206′ can serve as a contact pad. A connecting element 304′ may be formed on the second circuit structure 200-2. The connecting element 304′ may be electrically connected to the conductive element 206′. Specifically, in accordance with some embodiments, the connecting element 304′ may be disposed corresponding to the conductive elements 206′ of the second circuit structure 200-2. That is, in the normal direction of the substrate 100 (for example, the Z direction in the figure), the connecting element 304′ may overlap with the conductive element 206′. Furthermore, in accordance with some embodiments, the connecting element 304′ may be further electrically connected to external electronic components. For example, the connecting element 304′ may be further electrically connected to a printed circuit board (PCB), a chip, a control element or another electronic component (not illustrated), but the present disclosure is not limited thereto.

Referring to FIG. 3C, the electronic device 30 includes a substrate 100, a through hole 100V, a first circuit structure 200-1 and an electronic unit 400. The substrate 100 includes a first side 100a and a second side 100b opposite to the first side 100a. The through hole 100V penetrates the substrate 100 and connects the first side 100a to the second side 100b. The first circuit structure 200-1 is disposed on the first side 100a of the substrate 100 and includes a metal layer 202 and a dielectric layer 203. The metal layer 202 overlaps a portion P1 of the first side 100a of the substrate 100, the dielectric layer 203 overlaps a portion P2 of the first side 100a of the substrate 100, and the portion P1 is connected to the portion P2. The electronic unit 400 is electrically connected to the first circuit structure 200-1. Furthermore, the surface roughness of the portion P1 is lower than the surface roughness of the portion P2. Similarly, in accordance with some embodiments, the ratio of the surface roughness of portion P2 to the surface roughness of portion P1 is greater than or equal to 1.02 and less than or equal to 1.5.

In accordance with some embodiments, the electronic device 30 may further include a buffer layer 102, and the buffer layer 102 may be disposed between the metal layer 202′ and the substrate 100. Furthermore, the buffer layer 102 may extend into the through hole 100V. In accordance with some embodiments, the electronic device 30 may further include a conductive layer 204′. The conductive layer 204′ may be disposed on the buffer layer 102 and extend into the through hole 100V. An end 204e of the conductive layer 204′ may protrude from an end 102e of the buffer layer 102 by a first distance G1. The first distance G1 may be less than or equal to 2 micrometers.

In accordance with some embodiments, the electronic device 30 may further include a second circuit structure 200-2, and the second circuit structure 200-2 is disposed on the second side 100b of the substrate 100. The second circuit structure 200-2 may include a metal layer 202′ and a dielectric layer 203′. The metal layer 202′ overlaps a portion P1′ of the second side 100b of the substrate 100, and the dielectric layer 203′ overlaps a second portion P2′ of the second side 100b of the substrate 100, and the portion P1′ is connected to the portion P2′. Furthermore, the surface roughness of the portion P1′ is smaller than the surface roughness of the portion P2′. In accordance with some embodiments, the ratio of the surface roughness of the portion P2′ to the surface roughness of the portion P1′ may be greater than or equal to 1.02 and less than or equal to 1.5.

Furthermore, in accordance with some embodiments, the electronic device 30 may further include a conductive element CD, and the conductive element CD may be disposed in the through hole 100V. The first circuit structure 200-1 may be electrically connected to the second circuit structure 200-2 through the conductive element CD. In accordance with some embodiments, the electronic device 30 may further include a conductive layer 204, a conductive element 206, a connecting element 302, a conductive element 206′, and a connecting element 304′. The conductive layer 204 and the conductive element 206 may be electrically connected to the metal layer 202. The first circuit structure 200-1 may be electrically connected to the electronic unit 400 through the connecting element 302. The conductive element 206′ and the connecting element 304 may be electrically connected to the metal layer 202′

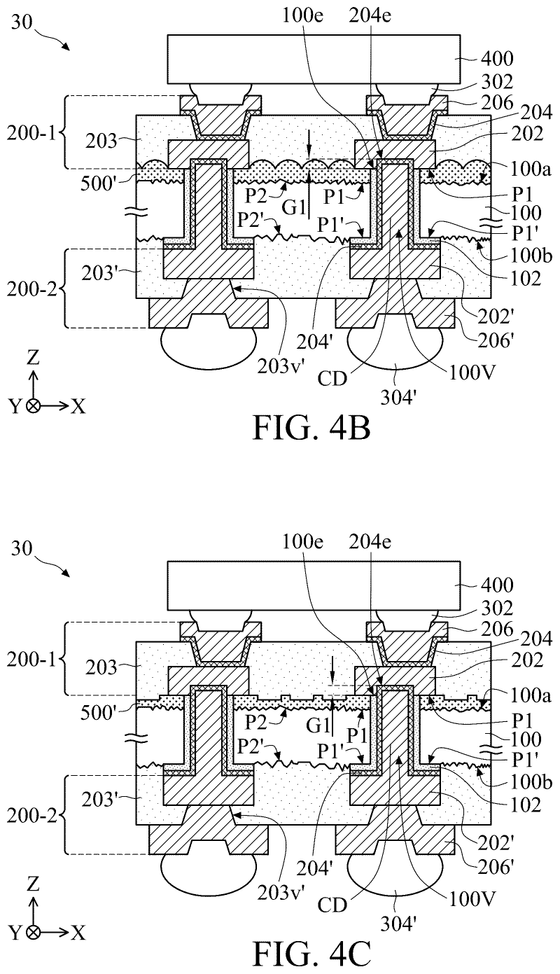

Please refer to FIGS. 4A to 4C, which are cross-sectional diagrams of an electronic device during the different stages of the manufacturing process in accordance with some embodiments of the present disclosure. Specifically, the electronic device shown in FIGS. 4A to 4C is substantially similar to FIG. 3C. Compared with FIG. 3C, the electronic device shown in FIGS. 4A to 4C may further include a dielectric layer 500 (dielectric layer 500′). In detail, the substrate 100 of the electronic device may further include a dielectric layer 500 (dielectric layer 500′) disposed thereon.

Referring to FIG. 4A, a substrate 100 includes a first side 100a and a second side 100b opposite to the first side 100a. Next, a metal layer 202 is formed on the substrate 100. In detail, in accordance with some embodiments, a photoresist may be formed on the substrate 100 first to define the position where the metal layer 202 is to be formed, and then the metal material is formed on the substrate 100, and then the photoresist is removed to expose a portion of the first side 100a of the substrate 100. Next, a dielectric layer 500 may be formed on the exposed first side 100a of the substrate 100.

In accordance with some embodiments, the material of the dielectric layer 500 may include polymer materials, such as perfluoroalkoxy alkane (PFA), polytetrafluoroethylene (PTFE), fluorinated ethylene propylene (FEP), polyethylene, silicone, acrylic, urethane or epoxy, another suitable material or a combination thereof, but it is not limited thereto. In accordance with some embodiments, the dielectric layer 500 may be formed by a coating process, a spraying process, a dispensing process, a printing process or another suitable method, but it is not limited thereto. Furthermore, the dielectric layer 500 may be patterned through a patterning process so that the surface of the dielectric layer 500 has a non-flat profile.

Please refer to FIG. 4B and FIG. 4C. In accordance with some embodiments, the patterned dielectric layer 500′ may be disposed on the substrate 100, and the surface roughness of the patterned dielectric layer 500′ is greater than the surface roughness of the surface of the first side 100a of the substrate 100 covered by the metal layer 202 (e.g., similar to portion P1 shown in FIG. 1B). In accordance with some embodiments, as shown in FIG. 4B, the surface of the patterned dielectric layer 500′ may have a wavy profile. In accordance with some embodiments, as shown in FIG. 4C, the surface of patterned dielectric layer 500′ may have a recessed profile.

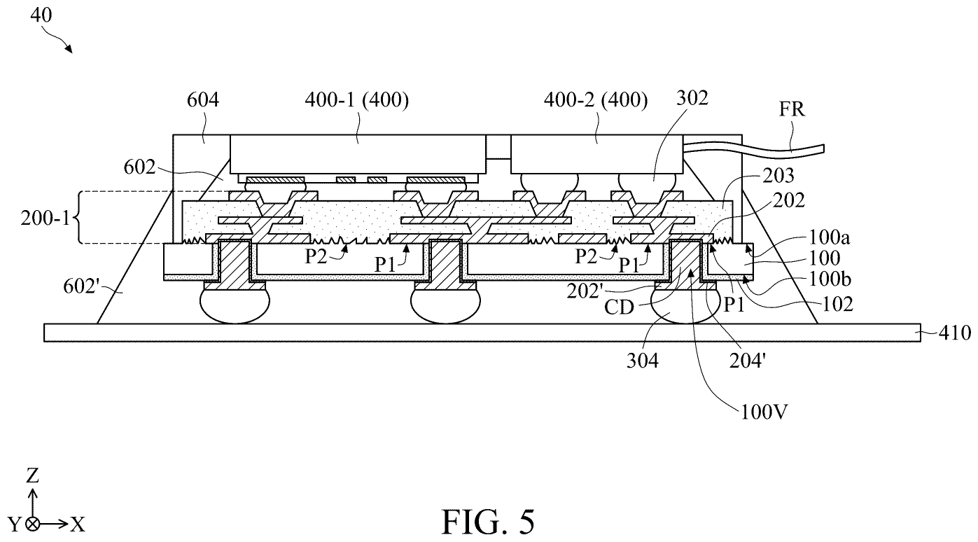

Please refer to FIG. 5, which is a cross-sectional diagram of an electronic device 40 in accordance with some other embodiments of the present disclosure. It should be understood that, for clarity of explanation, some components of the electronic device 40 may be omitted in the drawings, and only some components are schematically illustrated. In accordance with some embodiments, additional features may be added to the electronic device 40 described below.

Specifically, the electronic device 40 may be formed based on the aforementioned manufacturing method of the electronic device 20 and with a suitable packaging method. For example, the electronic device 40 can be applied to co-packaged optics (CPO), but the present disclosure is not limited thereto.

As shown in FIG. 5, the electronic device 40 has a similar structure to the electronic device 20, and may further include an insulating layer 602. The insulating layer 602 may be disposed between the electronic unit 400 and the first circuit structure 200-1. The insulating layer 602 may be in contact with the connecting element 302 and the electronic unit 400. In accordance with some embodiments, the insulating layer 602 may be partially formed on the side surface of the electronic unit 400. The insulating layer 602 can reduce the influence of water and oxygen on the electronic unit 400 from the external environment. In accordance with some embodiments, the insulating layer 602 may have a sloped surface, but it is not limited thereto.

In accordance with some embodiments, the insulating layer 602 may include molding compound, epoxy, another suitable encapsulating material, or a combination thereof, but it is not limited thereto. In accordance with some embodiments, the insulating layer 602 may be formed by a compression molding process, a transfer molding process, or another suitable method. In accordance with some embodiments, the insulating layer 602 may be in a liquid or semi-liquid form during the molding process and then solidified.

Furthermore, the electronic device 40 may further include an encapsulation layer 604. The encapsulation layer 604 may surround the electronic unit 400, and the encapsulation layer 604 may be in contact with the electronic unit 400, the insulating layer 602, the first circuit structure 200-1 and the substrate 100. The encapsulation layer 604 can reduce the influence of water and oxygen on the electronic unit 400 from the external environment. In accordance with some embodiments, the encapsulation layer 604 may include molding compound, epoxy resin, another suitable encapsulation material, or a combination thereof, but it is not limited thereto. Furthermore, the material of the encapsulation layer 604 may be the same as or different from the material of the insulating layer 602. In accordance with some embodiments, the encapsulation layer 604 may be formed by a compression molding process, a transfer molding process, or another suitable method. In accordance with some embodiments, the encapsulation layer 604 may be in a liquid or semi-liquid form during the molding process and then solidified.

Furthermore, the electronic device 40 may further include an electronic unit 410 bonding to the connecting element 304. The first circuit structure 200-1 may be electrically connected to the electronic unit 410 through the conductive element CD and the connecting element 304. For example, the electronic unit 410 may be a printed circuit board, but it is not limited thereto. In addition, an insulating layer 602′ may be further formed between the electronic unit 410 and the substrate 100. The insulating layer 602′ may be in contact with the electronic unit 410, the substrate 100, the connecting element 304 and the insulating layer 602. In accordance with some embodiments, the insulating layer 602′ may be partially formed on the side surface of the insulating layer 602. The insulating layer 602′ can reduce the influence of water and oxygen in the external environment on the metal layer 202′ and the connecting element 304, thereby maintaining the quality of electrical connection. Moreover, the material and formation method of the insulating layer 602′ may be the same as or similar to that of the insulating layer 602.

In addition, the electronic device 40 may include several electronic units 400. For example, the first circuit structure 200-1 may be electrically connected to an electronic unit 400-1 and an electronic unit 400-2 through the connecting element 302. In accordance with some embodiments, the electronic unit 400-1 may include, for example, a known good die (KGD), an integrated circuit die (IC), a surface mount device (SMD), a diode, or another suitable electronic component, but it is not limited thereto. Furthermore, in accordance with some embodiments, the electronic unit 400-2 may include, for example, a photonic integrated circuit (PIC), which may be connected to an optical fiber FR for transmitting and processing optical signals. As described above, the electronic device 40 can co-package the optical chip module and the electronic chip module together to form a co-packaged optic (CPO).

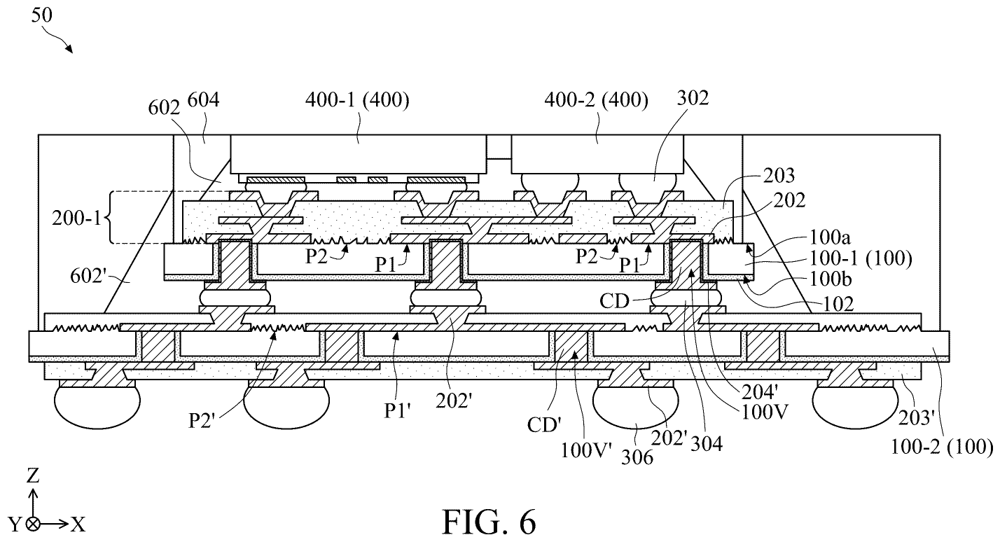

Please refer to FIG. 6, which is a cross-sectional diagram of an electronic device 50 in accordance with some other embodiments of the present disclosure. It should be understood that, for clarity of explanation, some components of the electronic device 50 may be omitted in the drawings, and only some components are schematically illustrated. In accordance with some embodiments, additional features may be added to the electronic device 50 described below.

Specifically, the electronic device 50 may be formed based on the aforementioned manufacturing method of the electronic device 20 and with a suitable packaging method. For example, the electronic device 50 can be applied to a structure similar to a Chip on Wafer on Substrate (CoWoS) package.

As shown in FIG. 6, the electronic device 50 has a similar structure to the electronic device 20, and may further include an insulating layer 602, a encapsulation layer 604, and an insulating layer 602′. For descriptions of the insulating layer 602, the encapsulation layer 604 and the insulating layer 602′, please refer to FIG. 5 and will not be repeated here.

Furthermore, the electronic device 50 may include several substrates 100. The substrate 100-1 may serve as an interposer substrate. The first side 100a of the substrate 100-1 may be surface treated such that the surface roughness of the portion P1 is lower than the surface roughness of portion P2. The substrate 100-2 can serve as another through-hole substrate. Specifically, the substrate 100-2 can have a through-hole 100V′, and the conductive element CD′ may be disposed in the through-hole 100V′. The substrate 100-2 may also have a through glass via (TGV) structure. The conductive material CD′ may be electrically connected to the conductive element CD through the metal layer 202′, and then electrically connected to the first circuit structure 200-1. Furthermore, the conductive material CD′ may be electrically connected to the connecting element 306 through the metal layer 202′, and the connecting element 306 may be further electrically connected to other external electronic components. In addition, the surface of the substrate 100-2 may also be surface treated so that the surface roughness of the portion P1′ is smaller than the surface roughness of the portion P2′. Specifically, the surface treatment process may roughen the portion P2′ that does not overlap with the metal layer 202′, while the portion P1′ that overlaps with the metal layer 202′ is not roughened.

In addition, the electronic device 50 may include several electronic units 400. For example, the first circuit structure 200-1 may be electrically connected to an electronic unit 400-1 and an electronic unit 400-2 through the connecting element 302. As mentioned above, the electronic unit 400-1 and the electronic unit 400-2 may include a system on a chip, a dynamic random access memory, a high-bandwidth memory, a photonic integrated circuit, an application-specific integrated circuit, or another logic integrated circuit. Furthermore, the type of the electronic unit 400-1 may be the same as or different from the electronic unit 400-2.

To summarize the above, according to embodiments of the present disclosure, the manufacturing method of an electronic device provided can improve the bonding strength between the through-hole substrate and other film layers of different materials, thereby improving the reliability and performance of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate comprising a first side and a second side opposite to the first side;
a through hole penetrating the substrate and connecting the first side to the second side;
a first circuit structure disposed on the first side of the substrate and comprising:
a first metal layer overlapping a first portion of the first side of the substrate; and
a first dielectric layer overlapping a second portion of the first side of the substrate, wherein the first portion is connected to the second portion; and an electronic unit electrically connected to the first circuit structure,
wherein a surface roughness of the first portion is lower than a surface roughness of the second portion.

2. The electronic device as claimed in claim 1, further comprising:
a buffer layer disposed between the first metal layer and the substrate.

3. The electronic device as claimed in claim 2, wherein the buffer layer extends into the through hole.

4. The electronic device as claimed in claim 1, further comprising:
a second circuit structure disposed on the second side of the substrate.

5. The electronic device as claimed in claim 4, further comprising:
a conductive element disposed in the through hole, wherein the first circuit structure is electrically connected to the second circuit structure through the conductive element.

6. The electronic device as claimed in claim 4, wherein the second circuit structure comprises:
a second metal layer overlapping a third portion of the second side of the substrate; and
a second dielectric layer overlapping a fourth portion of the second side of the substrate, wherein the third portion is connected to the fourth portion, and a surface roughness of the third portion is lower than a surface roughness of the fourth portion.

7. The electronic device as claimed in claim 1, wherein the substrate comprises glass.

8. The electronic device as claimed in claim 1, wherein a ratio of the surface roughness of the second portion to the surface roughness of the first portion is greater than or equal to 1.02 and less than or equal to 1.5.

9. The electronic device as claimed in claim 2, further comprising:
a conductive layer disposed on the buffer layer and extending into the through hole, wherein an end of the conductive layer protrudes from an end of the buffer layer by a first distance, and the first distance is less than or equal to 2 micrometers.

10. The electronic device as claimed in claim 1, further comprising:
a patterned dielectric layer disposed on the substrate, wherein a surface roughness of the patterned dielectric layer is greater than the surface roughness of the first portion of the substrate.

11. The electronic device as claimed in claim 9, wherein a surface of the patterned dielectric layer has a wavy profile or a recessed profile.

12. A method of manufacturing an electronic device, comprising:
providing a substrate comprising a first side and a second side opposite to the first side;
forming a through hole penetrating the substrate, wherein the through hole connects the first side to the second side;
forming a first circuit structure on the first side of the substrate, wherein forming the first circuit structure comprises:
forming a first metal layer on the first side of the substrate; and
forming a first dielectric layer on the first side of the substrate and covering the first metal layer, wherein the first metal layer overlaps a first portion of the first side of the substrate, the first dielectric layer overlaps a second portion of the first side of the substrate, and the first portion is connected to the second portion; and
performing a surface treatment process on the first side of the substrate so that a surface roughness of the first portion is lower than a surface roughness of the second portion; and
forming an electronic unit electrically connected to the first circuit structure.

13. The method of manufacturing an electronic device as claimed in claim 12, wherein after performing the surface treatment process on the first side of the substrate, the first dielectric layer is formed on the first side of the substrate and covering the first metal layer.

14. The method of manufacturing an electronic device as claimed in claim 12, wherein after forming the through hole penetrating the substrate, the first circuit structure is formed on the first side of the substrate.

15. The method of manufacturing an electronic device as claimed in claim 12, wherein before forming the through hole penetrating the substrate, the first circuit structure is formed on the first side of the substrate.

16. The method of manufacturing an electronic device as claimed in claim 12, further comprising:
forming a buffer layer on the substrate and extending into the through hole.

17. The method of manufacturing an electronic device as claimed in claim 16, further comprising:
forming a conductive layer on the buffer layer, wherein the conductive layer extends into the through hole, an end of the conductive layer protrudes from an end of the buffer layer by a first distance, and the first distance is less than or equal to 2 micrometers.

18. The method of manufacturing an electronic device as claimed in claim 12, further comprising:
forming a second circuit structure on the second side of the substrate; and
forming a conductive element in the through hole, wherein the first circuit structure is electrically connected to the second circuit structure through the conductive element.

19. The method of manufacturing an electronic device as claimed in claim 12, wherein the surface treatment process comprises a laser roughening process, a chemical etching process, a mechanical grinding process or a combination thereof.

20. The method of manufacturing an electronic device according to claim 12, wherein a ratio of the surface roughness of the second portion to the surface roughness of the first portion is greater than or equal to 1.02 and less than or equal to 1.5.
